(19) United States
(12) Patent Application Publication
(10) Pub. No.: US 2004/0154733 A1
(43) Pub. Date: Aug. 12, 2004

(54) Chip transfer method and apparatus

(76) Inventor: Thomas Morf, Gross (CH)

Correspondence Address: Robert M Trepp, IBM Corporation, Intellectual Property Law Dept, P O Box 218, Yorktown Heights, NY, 10598-0218, US

(21) Appl. No.: 10/467,584

(22) PCT Filed: Feb. 4, 2002
(86) PCT No.: PCT/IB02/00367

(30) Foreign Application Priority Data
Feb. 8, 2001 (EP) 01810130.3

(51) Int. Cl. B32B 31/18; H01L 21/78

(52) U.S. Cl. 156/241; 156/290; 156/344

(57) ABSTRACT

The invention is directed to a method for transferring an integrated-circuit element from a source substrate to a predetermined position on a target substrate. A source substrate with an integrated-circuit element on it and an element transfer holder with a layer of an adhesive material with a controllable adhesivity are provided. The element transfer holder is lowered onto the integrated-circuit element whereby the adhesivity has a first value suited to hold the integrated-circuit element to the element transfer holder. Then the integrated-circuit element is released from the source substrate and the element transfer holder with the integrated-circuit element attached to it is removed from the source substrate. The target substrate is provided with a droplet of a liquid arranged at the predetermined position and the element transfer holder is lowered with the integrated-circuit element attached to it onto the target substrate such that the integrated-circuit element gets into contact with the droplet. Then the adhesivity of the adhesive material is set to a second value suited to release the integrated-circuit element from the element transfer holder whereby the droplet aligns the integrated-circuit element to the predetermined position. Finally the element transfer holder is removed from the integrated-circuit element.

The invention relates to a method for transferring an integrated-circuit element from a source substrate to a predetermined position on a target substrate and an apparatus therefor. More specifically the invention relates to a method of transferring VCSEL chips or other optical or non-optical components on landing areas of silicon-substrate-based chips.

### TECHNICAL FIELD AND BACKGROUND OF THE INVENTION

Presently, chip-to-chip communication is going through a major evolution. The TTL-level communication is no longer capable of handling the tremendous amount of data which needs to be transferred between chips. Several approaches for parallel high-speed links are being developed. Using such techniques, significant higher data rates can be handled by the limited number of IC pins, which are mechanically feasible. However, it is foreseen that a hard limit of about 1 TB/s exists due to cost issues of packages with more than 1500 pins. In addition, signal loss, dispersion and permissible chip power, limit the bit rate of interconnects to about 10 GB per second per pin. A solution would be to use an optical channel not only for long-distance communication but also for short-distance chip-to-chip communication. Optical interconnect requires however a light source. Especially desirable for these applications are Vertical-Cavity Surface-Emitting Lasers (VCSEL). The goal is to replace the electrical IOs of large silicon CMOS chips with optical interconnects. Unfortunately, silicon is due to its indirect bandgap not a usable material for lasers or LEDs. As a result, an off-chip laser has to be used which creates severe assembly problems. A short electrical interconnect is again necessary to connect the CMOS chip with the external laser chip. This interconnect may be short but will already be problematic due to parasitic capacitances. In addition the mounting of several hundred lasers is very cost-intensive. A large single-chip laser array is not feasible since each pin of the CMOS chip needs a laser in close proximity.

Several research groups tried to solve the problem by growing a thin layer of e.g. GaAs on Si. This would enable the monolithical integration of lasers on a silicon chip. Unfortunately, growing GaAs on Si is very difficult due to the large difference in lattice constant.

Other groups developed techniques to transfer thin GaAs layers onto silicon. The idea is to transfer a thin (less than one micron to several microns) layer of III/V semiconductor material containing a laser or another optical component. The laser characteristics will not change due to the transfer. Since the layer is so thin, interconnection between the CMOS circuit and the laser can be done with a standard metallization technique, e.g. the last metallization level of the CMOS chip. The result is a monolithic integration of a CMOS circuit with e.g. lasers. The limitation of this technique so far was, that it is a rather manual process. Presently one laser is transferred manually at a time making it unusable in any commercially efficient manufacturing process.

In “Epitaxial Lift-off Applications in Microwave Circuits and Optoelectronics” by T. E. Morf, Diss. ETH Nr. 11800, 1996 an overview over the epitaxial lift-off process is given which can be used to separate devices from their substrate and enable those devices to be transferred to a target substrate. For picking up the devices a vacuum gripper can be used.

A principle of alignment of transferred devices under use of water droplets is described in “Fabrication of long wavelength OEICs using GaAs on InP epitaxial lift-off technology”, by I. Pollentier, P. Demeester, P. Van Daele, D. Rondi, G. Glastre, A. Enard, and R. Blondeau, in Proc. Third Int. Conf. on InP and Related Materials, New York, USA, 1991, pp.268-71.

### OBJECT AND ADVANTAGES OF THE INVENTION

The invention described here is an assembly process, which can be used to transfer vertical-cavity surface-emitting lasers (VCSEL) and photo diodes on a wafer scale. Hundreds or even thousands of lasers and photo diodes can be transferred simultaneously to a CMOS wafer.

According to a first aspect of the invention a method is provided for transferring an integrated-circuit element from a source substrate to a predetermined position on a target substrate.

According to a second aspect of the invention an apparatus is provided for transferring an integrated-circuit element from a source substrate to a predetermined position on a target substrate.

According to a third aspect of the invention the method and apparatus allow the simultaneous transfer of a multitude of integrated-circuit elements.

According to a fourth aspect of the invention the method and apparatus allow a selective transfer of the integrated-circuit elements onto one or more target substrates.

According to a fifth aspect of the invention the integrated-circuit elements undergo an automatic alignment on the target substrate.

### SUMMARY OF THE INVENTION

The invention is directed to a method for transferring an integrated-circuit element from a source substrate to a predetermined position on a target substrate. In a first step an element transfer holder that has an adhesive layer comprising an adhesive material with a controllable adhesivity is lowered onto the integrated-circuit element that is located on a source substrate. The adhesivity has a first value suited to hold the integrated-circuit element to the element transfer holder. In a second step the element transfer holder is moved with the integrated-circuit element attached to it towards a target substrate that has a droplet of a liquid arranged at the predetermined position. In a third step the element transfer holder with the integrated-circuit element attached to it is lowered onto the target substrate such that the integrated-circuit element gets into contact with the droplet. In a fourth step the adhesivity of the adhesive layer is set to a second value suited to release the integrated-circuit element from the element transfer holder whereby the droplet aligns the integrated-circuit element to the predetermined position. Finally the element transfer holder is removed.

The technique described here can be seen as a further development of the epitaxial lift-off (ELO) technique. The basic idea of ELO is to release a thin film piece of III/V material and transfer this film piece on a new host material. The film will stick to the new host material by Van-der-Waals forces. The critical steps are releasing the film from its growth substrate and transferring and aligning it. The latter is according to the state of the art done with a manual pick-and-place process, operating on single film pieces making it unusable in any commercial manufacturing process. The present invention is supposed to allow to eliminate this manual process by an automated wafer-scale process.

It is of advantage when the element transfer holder is aligned with the source substrate via an alignment element because thereby an alignment of the integrated-circuit element with respect to the element transfer holder is achievable that allows subsequently a precise control of the adhesivity in the area of the integrated-circuit element.

Before the second step the integrated-circuit element can be released from the source substrate by removing the source substrate or a sacrificial layer underneath the integrated-circuit element. This has the advantage that then the integrated-circuit element is isolated and can be transferred as a single element to the target substrate. Several integrated-circuit elements can thereby be manufactured on the same substrate and be isolated from each other to be transferred selectively. For separating several such integrated-circuit elements from each other, trenches can be provided between the integrated-circuit elements, e.g. by etching,

An easy, cheap and quick solution of providing the adhesive layer is to bring the element transfer holder into contact with a surface of a reservoir containing the adhesive material and removing the element transfer holder from the reservoir. The adhesive layer can also be stamped, sprayed or applied via a roller, blade or brush to the element transfer holder. Stamping or the bringing into contact with a reservoir has the advantage of allowing a very homogeneous thickness of the adhesive layer which is advantageous in that the adhesivity can be more accurately controlled.

If the element transfer holder is provided structured to have for the integrated-circuit element a holding area with essentially the lateral dimension of the integrated-circuit element, there is a predetermined area for the integrated-circuit element. This allows better alignment of the integrated-circuit element onto the element transfer holder, e.g. by using the structural edges of the holding area. Also the adhesivity of the adhesive layer for the integrated-circuit element can be controlled in essentially only its holding area. This allows selective attaching and/or releasing of the integrated-circuit elements at the element transfer holder. Even different integrated-circuit elements can be attached to the same element transfer holder.

An easy and nevertheless selective alignment can be provided by using the liquid droplet. As droplet herein is to be understood a confined amount of the liquid. This droplet can hence also be a thin liquid film. The droplet of the liquid can be advantageously arranged at the predetermined position by applying the liquid to the target substrate which comprises a wettability-structured layer that is hydrophilic at the predetermined position. Thereby simply applying the liquid to the whole target substrate will nevertheless leave the liquid droplets only at those positions that are predetermined by the wettability-structure. The wettability-structure can be applied by a lithographic process or a stamping step. No active alignment of the liquid droplets has to be carried out and the risk is reduced that the droplet leaves its position e.g. due to environmental influences like gravity or air flow. The wettability-structure also effects an automatic limitation of the liquid amount contained in the droplet. The surface tension of the liquid droplet is then suited to effect the alignment of the integrated-circuit element.

Using a thermally controllable adhesive layer allows to use heaters for controlling the adhesivity. This provides a very cheap and easily realizable way of controlling. Integrating heaters into the element transfer holder is feasible by using current-induced heating, e.g. by providing a coil or meandric wire structure that for being heated is set under current. The heat is well controllable even locally, whereby a material for the element transfer holder is advantageous that provides for a heat conductivity that does essentially not allow the heat present at the position of one integrated-circuit element to control the adhesivity at the position of another integrated-circuit element. Thereby a selective adhesivity control is achievable.

### DESCRIPTION OF THE DRAWINGS

Examples of the invention are depicted in the drawings and described in detail below by way of example. It is shown in

FIG. 1. an element transfer holder wafer above integrated-circuit elements on a source substrate,

FIG. 2 the element transfer holder with integrated-circuit elements attached above a target substrate with wetted landing areas,

FIG. 3 the target substrate with two deposited integrated-circuit elements with the element transfer holder removed.

All the figures are for sake of clarity not shown in real dimensions, nor are the relations between the dimensions shown in a realistic scale.

### DETAILED DESCRIPTION OF THE INVENTION

In the following, the various exemplary embodiments of the invention are described.

A CMOS wafer 2, being shown in FIG. 2, containing several chips is processed using any known CMOS process. Here, the process is stopped after the last metallization step. The chips have landing areas 12 for integrated-circuit elements 3, which here are VCSELs 3. The landing areas 12 are here signal pads where optical input is required. The whole CMOS wafer 2 is then made hydrophobic except for the landing areas 12. Therefor it is covered with a wettability-structured layer 15 which is structured to leave the landing areas 12 hydrophilic while the rest of the wettability-structured layer 15 is hydrophobic. This CMOS wafer 2 is also referred to as target substrate 2 for the VCSELs 3 which represent integrated-circuit elements 3. The landing areas 12 are predetermined positions 12 for these integrated-circuit elements 3. The CMOS wafer 2 is held on a target substrate holder 5.

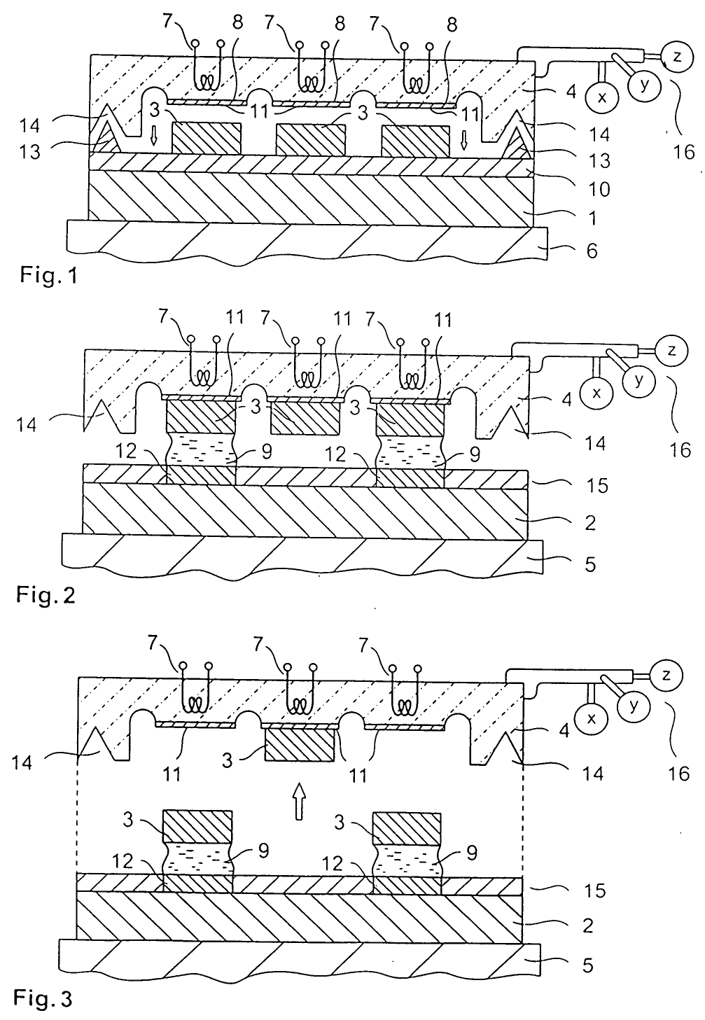

As depicted in FIG. 1, the VCSELs 3 are fabricated on a VCSEL wafer 1 with an etch-stop layer 10 underneath the VCSELs 3. For manufacturing the VCSELs 3 any standard VCSEL process can be used. Several millions of VCSELs 3 measuring e.g 50 μm×50 μm can be processed on a standard 4-inch GaAs wafer, which results in low-cost devices. The VCSEL wafer 1 is hereinafter also referred to as source substrate 1, being held on a source substrate holder 6.

Next, trenches are etched between all VCSELs 3 from the top surface of the VCSEL wafer 1. The trenches reach the etch-stop layers 10 whereby the VCSELs 3 are separated from each other. This can be done using a conventional dry-etching technique. At the same time alignment elements 13 can be created on the VCSEL wafer 1. The resulting structure is depicted in the lower part of FIG. 1

In FIG. 1 also an element transfer holder 4 is shown. The element transfer holder 4 in the form of a silicon wafer is used for a subsequent transplantation process, i.e. transferring the integrated-circuit elements 3 from the source substrate 1 to the target substrate 2. This element transfer holder 4 can be of the same size as the VCSEL wafer 1. In this element transfer holder 4 trenches are present to form on the lower surface a waffle pattern whereby the waffles may be a bit larger than the VCSELs 3, e.g. 70 μm×70 μm. These waffles are individually heatable by an electrical current. Therefor an array of heaters 7 is arranged on the element transfer holder 4. Additionally the element transfer holder 4 comprises counteralignment elements 14 which correspond to the alignment elements 13. The element transfer holder 4 is controllable in its position via a holder mover 16 which here provides for a movability in all 3 dimensions. The element transfer holder 4 is arranged with the waffle-structured surface down as shown in FIG. 1.

For enabling the element transfer holder 4 to transfer the VCSELs 3 from the VCSEL wafer 1, which is the source substrate 1, to the target substrate 2, the element transfer holder 4 is supplied with an adhesive layer 8 which is a layer comprising an adhesive material. This adhesive layer 8 has the property of the adhesivity being variable depending on an external influence which is controllable. Here the adhesivity is controllable via a thermal influence, the heaters 7 serving as adhesivity controllers 7.

As the adhesive material a small amount of wax has been applied to the waffles by stamping, i.e. the VCSEL wafer 1 is brought into contact with a wax supply whereby the wax sticks to the protruding waffle areas, short referred to as waffles, intended to serve as holding areas 11 for the VCSELs 3. Hence the element transfer holder 4 comprises as the adhesive layer 8 a patterned wax layer 8 whereby each waffle's wax layer 8 is separately controllable in its adhesivity.

These heaters 7 can be buried in the element transfer holder 4 and hence be situated close to the waffle patterned surface but also be realized in form of a structure on the upper surface of the element transfer holder 4. Also an arrangement of the heaters 7 on the lower surface of the element transfer holder 4, directly between the element transfer holder 4 and the adhesive layer 8 is feasible which provides the best controllability of the adhesivity.

Next, the element transfer holder 4 is placed onto the VCSEL wafer 1. The wax thereby makes contact to the VCSELs 3. Via the alignment structures 13 an alignment within 10 μm is feasible. The element transfer holder 4 will seal the top part of the VCSELs 3 in the following etching step. The VCSEL wafer 1 is then etched from the back side until the etch-stop layer 10 is reached. For accelerating this process, the VCSEL wafer 1 could be mechanically thinned down to a first thickness, e.g. by grinding, whereby a thickness of 25 μm can be achieved, and afterwards be etched away. Since etching is the slower process, the mechanical thinning provides for a quicker substrate removal. Next, the etch-stop layer 10 is etched away in a second etching step which could be also unified with the first etching step. After this step all VCSELs 3 each are only connected to the element transfer holder 4 by the wax layer 8. The element transfer holder 4 with the single VCSELs 3 attached to the wax-covered waffles 11 is depicted in FIG. 2. An alternative to the substrate removal could be a lift-off process wherein the etch-stop layer 10 is removed and not the whole substrate of the VCSEL wafer 1. An etchant could reach the etch-stop layer 10 from the side. To accelerate this process it would be of advantage to have this etchant reach the etch-stop layer 10 also at other locations. There is space between the VCSELs 3 where this etchant can flow through but it is also possible to provide channels in the element transfer holder 4 or the VCSEL wafer 1 that allow the etchant to flow towards the etch-stop layer 10. Once the etch-stop layer 10 is removed, a separation of the VCSELs 3 from the VCSEL wafer 1 is possible.

The CMOS wafer 2, i.e. the target substrate 2, is dipped in deionized water. Because the target substrate 2 is everywhere hydrophobic except for the landing areas 12 for the VCSELs 3, water droplets 9 thereby form in the landing areas 12 only. The rest of the CMOS wafer 2 remains dry. The water droplets 9 on the target substrate 2 are then used for an automatic alignment of the VCSELs 3 on the landing areas 12 of the target substrate 2.

The VCSELs 3 hanging at the element transfer holder 4 are then brought into contact with the water droplets 9 on the CMOS wafer 2 as depicted in FIG. 2. By selectively heating and thereby melting the wax layer 8, selected VCSELs 3 will be released. The wax holding these VCSELs 3 becomes liquid and the adhesivity of the wax layer 8 is reduced such that the VCSELs 3 will no longer stick to the element transfer holder 4 and get into the influence of the water droplets 9. The VCSELs 3 will self-align within a few micrometers to the predefined landing areas 12 on the CMOS wafer 2. It is of advantage if the VCSELs 3 have sharp edges at their upper side which substantially prevents the wax from flowing down and negatively influencing the reliability of the transfer process and thereby the later functionality of the final arrangement. Since the VCSELs 3 however have a thickness of typically 7 μm, this dimension provides a safety margin for a possible wax flow. The element transfer holder 4 is then removable, leaving behind those VCSELs 3 which have been released in the preceding step. The result is shown in FIG. 3.

The wax hence stays substantially at the element transfer holder 4 and also those VCSELs 3 that have not been released. The water on the target substrate 2 is allowed to evaporate which can be accelerated by heat. Once the water has vanished, the VCSELs 3 lie on the landing areas 12. A possible wax rest on the VCSELs 3 may be removed by a cleaning step using a solvent or the like. Typically then Van-der-Waals forces keep the VCSELs 3 in place, particularly when the VCSELs 3 are additionally shortly pressed once against the landing areas 12. Also, a glue or soldering the VCSELs 3 to the landing areas 12 by use of a metal can be used. This provides advantageous in case a VCSEL 3 is used that comprises its contact pads at its underside which comes to lie on the target substrate 2. Then, the wiring for the VCEL contact can be premanufactured on the target substrate 2 and after having deposited the VCESEL 3 on its landing area 12, the VCEL contacts can be connected to the wiring by applying heat to the contact area.

Several hundred to thousands of VCSELs 3 can be transferred simultaneously by this method. The VCSEL wafer 1 and the element transfer holder 4 will most likely be smaller than the CMOS wafer 2. For depositing the VCSELs 3 at arbitrary locations on the CMOS wafer 2, the element transfer holder 4 can be moved over the CMOS wafer 2 and VCSELs 3 will be released at the desired locations.

In case the VCSELs 3 have one or more electrical contacts at their upper side, a wiring to this side is necessary. A patterned metallization step can be conducted after the VCSELs 3 have been positioned on the target substrate 2, but in case the vertical dimension of the VCSELs 3 is too high, the metallization could fail. For that a support material can be arranged at the VCSELs 3 which smoothes the transition from the target substrate 2 to the upper side of the VCSELs 3. A patterned polyimide layer can be used therefor.

As the adhesive material 8 also other materials that are thermally or otherwise controllable in their adhesivity are suitable. Also an electrostatic field can be used as adhesive force. Instead of water also other liquids can be used for the alignment.

The element transfer holder 4 is designed to be reused.

Any disclosed embodiment may be combined in part as well as in whole with one or several of the other embodiments shown and/or described. This is also possible for one or more features of the embodiments. It is obvious that a person skilled in the art can modify the shown arrangements in many ways without departing from the gist of the invention which is encompassed by the subsequent claims.

1. Method for transferring an integrated-circuit element (3) from a source substrate (1) to a predetermined position (12) on a target substrate (2), comprising
a) lowering in a first step an element transfer holder (4) that has an adhesive layer (8) comprising an adhesive material with a controllable adhesivity onto the integrated-circuit element (3) that is located on a source substrate (1) whereby the adhesivity has a first value suited to hold the integrated-circuit element (3) to the element transfer holder (4),
b) moving in a second step the element transfer holder (4) with the integrated-circuit element (3) attached to it towards a target substrate (2) that has a droplet (9) of a liquid arranged at the predetermined position (12),
c) lowering in a third step the element transfer holder (4) with the integrated-circuit element (3) attached to it onto the target substrate (2) such that the integrated-circuit element (3) gets into contact with the droplet (9),
d) setting in a fourth step the adhesivity of the adhesive layer (8) to a second value suited to release the integrated-circuit element (3) from the element transfer holder (4) whereby the droplet (9) aligns the integrated-circuit element (3) to the predetermined position (12),
e) removing in a fifth step the element transfer holder (4).

2. Method according to claim 1 wherein in the first step the element transfer holder (4) is aligned with the source substrate (1) via an alignment element (13).

3. Method according to claim 1 or 2 wherein before the second step the integrated-circuit element (3) is released from the source substrate (1) by removing the source substrate (1) or a sacrificial layer underneath the integrated-circuit element (3).

4. Method according to one of claims 1 to 3 wherein the adhesive layer (8) is provided on the element transfer holder (4) by bringing the element transfer holder (4) into contact with a surface of a reservoir containing the adhesive material and removing the element transfer holder (4) from the reservoir.

5. Method according to one of claims 1 to 4 wherein the element transfer holder (4) is provided structured to have for the integrated-circuit element (3) a holding area (11) with essentially the lateral dimension of the integrated-circuit element (3).

6. Method according to claim 5 wherein the adhesivity of the adhesive layer (8) for the integrated-circuit element (3) is controlled in essentially only its holding area (11).

7. Method according to one of claims 1 to 6 wherein the droplet (9) of the liquid is arranged at the predetermined position (12) by applying the liquid to the target substrate (2) which comprises a wettability-structured layer (15) that is hydrophilic at the predetermined position (12).

8. Method according to one of claims 1 to 7 wherein the adhesive material comprises a thermally controllable material such as wax.

9. Apparatus for transferring an integrated-circuit element (3) to a predetermined position (12) at a target substrate (2), the apparatus comprising
a) an element transfer holder (4) with an adhesive layer (8) comprising an adhesive material with a controllable adhesivity, for holding to it the integrated-circuit element (3),
b) an adhesivity controller (7) for controlling the adhesivity of the adhesive layer (8).

10. Apparatus according to claim 9 additionally comprising a holder mover (16) for lowering the element transfer holder (4) onto the integrated-circuit element (3) on a source substrate (1), furthermore for moving the element transfer holder (4) with the integrated-circuit element (3) attached to its adhesive layer (8) to the target substrate (2), and for removing the element transfer holder (4) from the integrated-circuit element (3).

11. Apparatus according to claim 9 or 10 additionally comprising a target substrate holder (5) and/or a source substrate holder (6).

12. Apparatus according to one of claims 9 to 11 additionally comprising a counteralignment element (14) that corresponds to an alignment element (13) at the source substrate (1).

13. Apparatus according to one of claims 9 to 12 wherein the adhesivity controller (7) is designed to control the adhesivity of the adhesive layer (8) essentially only in a holding area (11) having essentially the lateral dimension of the integrated-circuit element (3).
